(19) United States
(12) Patent Application Publication
(10) Pub. No.: US 2025/0309900 A1
(43) Pub. Date: Oct. 2, 2025

(54) LOGIC GATE CIRCUIT

(71) Applicant: CHIP-GAN POWER SEMICONDUCTOR CORPORATION, HSINCHU CITY (TW)

(72) Inventors: KE-HORNG CHEN, HSINCHU CITY (TW); KUO-LIN ZHENG, HSINCHU CITY (TW); YU-CHOU KO, HSINCHU CITY (TW); KE-MING SU, HSINCHU CITY (TW); YING-FENG WU, HSINCHU CITY (TW); CHUN-CHIEH KUO, HSINCHU CITY (TW); SHANG-CHIANG CHIN, HSINCHU CITY (TW)

(21) Appl. No.: 18/745,071

(22) Filed: Jun. 17, 2024

(30) Foreign Application Priority Data
Mar. 27, 2024 (TW) 113111332

(51) Int. Cl. H03K 19/094

(52) U.S. Cl. CPC H03K 19/094

(57) ABSTRACT

A logic gate circuit includes a first N-type transistor circuit, a second N-type transistor circuit, a capacitor, and a clamping circuit. Each of the first N-type transistor circuit and the second N-type transistor circuit includes at least one N-type transistor. The first N-type transistor circuit has a first terminal, a second terminal, and a third terminal. The second N-type transistor circuit has a fourth terminal and a fifth terminal. The fourth terminal is coupled to the third terminal. The capacitor is coupled between the first terminal and the third terminal. The clamping circuit is coupled to the first terminal and configured to clamp the voltage of the first terminal.

### BACKGROUND OF THE INVENTION

This application claims priority for the TW Application No. 113111332 filed on 27 Mar. 2024, the content of which is incorporated by reference in its entirely.

### FIELD OF THE INVENTION

The present disclosure relates to a logic gate circuit, particularly to a logic gate circuit without P-type transistors.

### DESCRIPTION OF THE RELATED ART

FIG. 1 shows a conventional logic gate circuit using a P-type transistor and an N-type transistor. The logic gate circuit 10 shown in FIG. 1 is an inverter. The logic gate circuit 10 includes a P-type transistor 12 and an N-type transistor 14. The P-type transistor 12 and the N-type transistor 14 may be enhancement-mode metal oxide semiconductor field effect transistors (MOSFETs). The gate 122 of the P-type transistor 12 is connected to an input 16. The source 124 of the P-type transistor 12 receives a power supply voltage VDD. The drain 126 of the P-type transistor 12 is connected to an output 18. The gate 142 of the N-type transistor 14 is connected to the input 16. The source 144 of the N-type transistor 14 is connected to a ground terminal GND. The drain 146 of the N-type transistor 14 is connected to the output 18. A control signal Vin provided to the input 16 switches the P-type transistor 12 and the N-type transistor 14 to generate an output signal Vout at the output 18. Specifically, when the control signal Vin is at a high level “1”, the P-type transistor 12 is turned off and the N-type transistor 14 is turned on, so that the output signal Vout is at a low level “0”. On the contrary, when the control signal Vin is at the low level “0”, the P-type transistor 12 is turned on and the N-type transistor 14 is turned off, so that the output signal Vout is at the high level “1”.

The conventional logic gate circuit 10 requires using P-type transistors. However, in some fabrication processes (e.g., processes for fabricating enhancement-mode GaN), P-type transistors cannot be fabricated. Thus, other components need to be used to replace the P-type transistors. FIG. 2 shows a logic gate circuit using a pull-up resistor instead of a P-type transistor. The logic gate circuit 20 shown in FIG. 2 is an inverter, which includes a pull-up resistor 22 and an N-type transistor 24, where the N-type transistor 24 can be an enhancement-mode MOSFET. The pull-up resistor 22 is connected between the power supply voltage VDD and the output 26. The gate 242 of the N-type transistor 24 receives a control signal Vin, the source 244 of the N-type transistor 24 is connected to a grounding terminal GND, and the drain 246 of the N-type transistor 24 is connected to the output 26. The control signal Vin switches the N-type transistor 24 to generate an output signal Vout at the output 26. Specifically, when the control signal Vin is at a high level “1”, the N-type transistor 24 is turned on, so that the output signal Vout is at a low level “0”. On the contrary, when the control signal Vin is at the low level “0”, the N-type transistor 24 is turned off, so that the output signal Vout is at the high level “1”.

However, when the N-type transistor 24 of the logic gate circuit 20 of FIG. 2 is turned on, a leakage current flows from the power supply voltage VDD to the grounding terminal GND, thereby causing additional power consumption. In addition, the output signal Vout needs to take a longer time to transition from the low level “0” to the high level “1” due to the pull-up resistor 22, causing the logic gate circuit 20 to have a slower response speed.

FIG. 3 shows a logic gate circuit using an N-type transistor instead of a P-type transistor. The logic gate circuit 30 shown in FIG. 3 is an inverter. The logic gate circuit 30 includes two N-type transistors 32 and 34 and an inverter 36. The N-type transistors 32 and 34 may be enhancement-mode MOSFETs. The gate 322 of the N-type transistor 32 is connected to the inverter 36, the drain 324 of the N-type transistor 32 is connected to a power supply voltage VDD, and the source 326 of the N-type transistor 32 is connected to an output 39. The gate 342 of the N-type transistor 34 is connected to an input 38, the source 344 of the N-type transistor 34 is connected to a grounding terminal GND, and the drain 346 of the N-type transistor 34 is connected to the output 39. The anode of the inverter 36 is connected to the input 38 and the cathode of the inverter 36 is connected to the gate 322. The inverter 36 inverts the control signal Vin on the input 38 to generate a control signal Vin_i. When the control signal Vin is at a high level “1”, the control signal Vin_i is at a low level “0”, so that the N-type transistor 32 is turned off and the N-type transistor 34 is turned on, thereby generating an output signal Vout of a low level “0”. On the contrary, when the control signal Vin is at a low level “0”, the control signal Vin_i is at a high level “1”, so that the N-type transistor 32 is turned on and the N-type transistor 34 is turned off, thereby generating an output signal Vout of a high level “1”.

In general, the voltage of the control signal Vin at the high level “1” is equal to the power supply voltage VDD. When the N-type transistor 32 is turned on, the voltage of the source 326 of the N-type transistor 32 is only VDD−VTH since the voltage difference between the gate 322 and the source 326 of the N-type transistor 32 must be greater than a threshold voltage VTH. In other words, when the N-type transistor 32 is turned on, the output voltage of the logic gate circuit 30 is not equal to the power supply voltage VDD, causing the logic gate circuit 30 not to have rail-to-rail characteristics.

### SUMMARY OF THE INVENTION

One of objectives of the present disclosure is to provide a logic gate circuit without using P-type transistors.

According to the present disclosure, a logic gate circuit includes a first N-type transistor circuit, a second N-type transistor circuit, a capacitor, and a clamping circuit. Each of the first N-type transistor circuit and the second N-type transistor circuit includes at least one N-type transistor. The first N-type transistor circuit has a first terminal, a second terminal, and a third terminal. The second N-type transistor circuit has a fourth terminal and a fifth terminal. The fourth terminal is coupled to the third terminal. The capacitor is coupled between the first terminal and the third terminal. The clamping circuit is coupled to the first terminal and configured to the voltage of the first terminal.

The logic gate circuit of the present disclosure can be applied in processes where P-type transistors cannot be fabricated. The logic gate circuit has a good response speed and rail-to-rail characteristics without consuming additional power caused by leakage current.

Below, the embodiments are described in detail in cooperation with the drawings to make easily understood the technical contents, characteristics and accomplishments of the present disclosure.

### BRIEF DESCRIPTION OF THE DRAWINGS

FIG. 1 shows a conventional logic gate circuit using a P-type transistor and an N-type transistor;

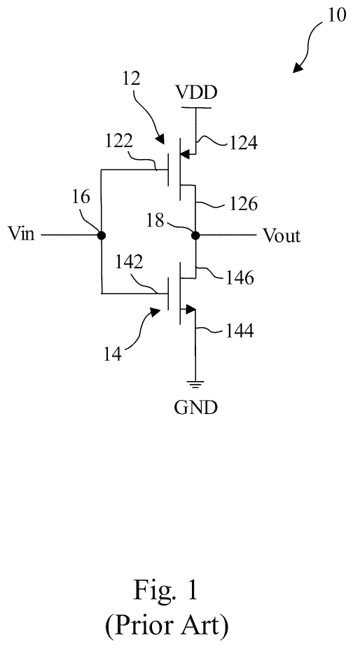

FIG. 2 shows a logic gate circuit using a pull-up resistor instead of a P-type transistor;

FIG. 3 shows a logic gate circuit using an N-type transistor instead of a P-type transistor;

FIG. 4 shows a logic gate circuit of the present disclosure;

FIG. 5 shows a logic gate circuit of FIG. 4 implemented with an inverter according to an embodiment of the present disclosure;

FIG. 6 shows a clamping circuit of FIG. 5 according to another embodiment of the present disclosure;

FIG. 7 shows a clamping circuit of FIG. 5 according to further embodiment of the present disclosure;

FIG. 8 shows a logic gate circuit of FIG. 4 implemented with a NAND gate according to an embodiment of the present disclosure; and

FIG. 9 shows a logic gate circuit of FIG. 4 implemented with a NOR gate according to an embodiment of the present disclosure.

FIG. 10 shows a schematic diagram of a power chip according to an embodiment of the present disclosure.

### DETAILED DESCRIPTION OF THE INVENTION

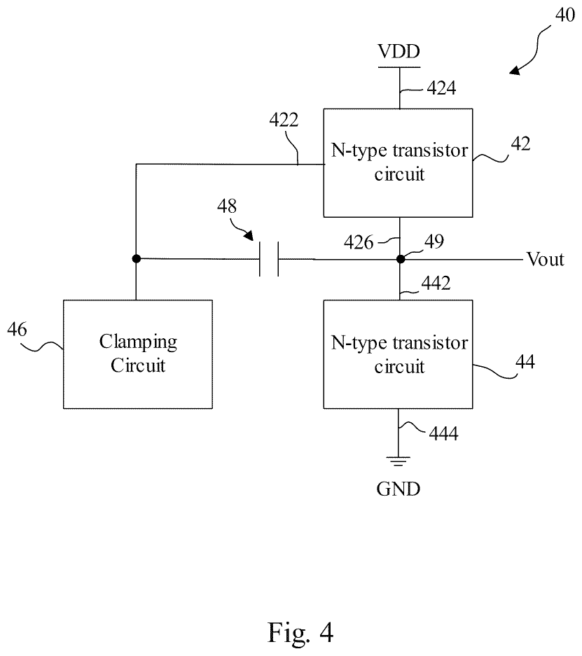

FIG. 4 shows a logic gate circuit of the present disclosure. In FIG. 4, a logic gate circuit 40 includes an N-type transistor circuit 42, an N-type transistor circuit 44, a clamping circuit 46, and a capacitor 48. Each of the N-type transistor circuits 42 and 44 includes at least one N-type transistor. The N-type transistor circuit 42 has a first terminal 422, a second terminal 424, and a third terminal 426. The second terminal 424 and the third terminal 426 are respectively coupled to a power supply voltage VDD and an output 49. The N-type transistor circuit 44 has a fourth terminal 442 and a fifth terminal 444 respectively coupled to the output 49 and a grounding terminal GND. The clamping circuit 46 is coupled to the first terminal 422 of the N-type transistor circuit 42 and configured to clamp the voltage of the first terminal 422. One end of the capacitor 48 is coupled to the first terminal of the N-type transistor circuit 42 and the clamping circuit 46 and another end of the capacitor 48 is coupled to the output 49. When the N-type transistor circuit 42 is turned on, the power supply voltage VDD is coupled to the output 49. When the N-type transistor circuit 44 is turned on, the output 49 is coupled to the grounding terminal GND.

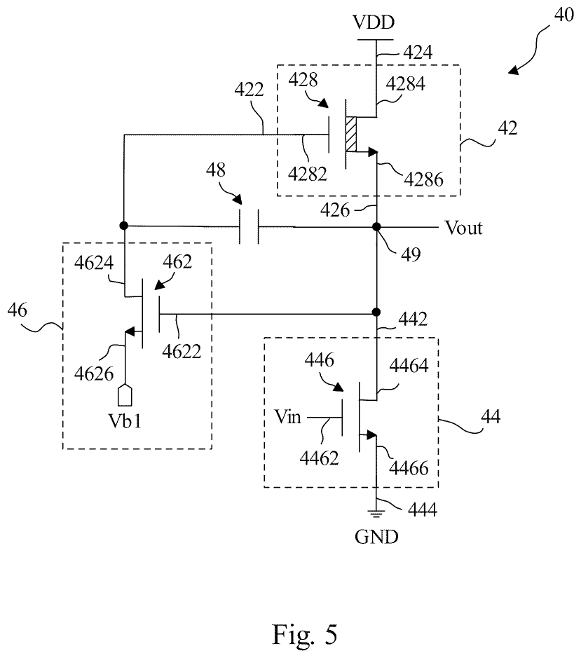

FIG. 5 shows a logic gate circuit shown in FIG. 4 implemented with an inverter according to an embodiment of the present disclosure. In FIG. 5, the N-type transistor circuit 42 includes an N-type depletion-mode GaN transistor 428, where the N-type depletion-mode GaN transistor 428 has a gate 4282, a drain 4284, and a source. 4286 respectively coupled to the first terminal 422, the second terminal 424, and the third terminal 426. The N-type transistor circuit 44 includes an N-type enhancement-mode GaN transistor 446, where the N-type enhancement-mode GaN transistor 446 has a gate 4462, a drain 4464, and a source 4466 respectively coupled to a control signal Vin1, the fourth terminal 442, and the fifth terminal 444. The clamping circuit 46 includes an N-type transistor 462 and a biasing voltage source Vb1. The N-type transistor 462 has a gate 4622, a drain 4624, and a source 4626 respectively coupled to the third terminal 426 (or the output 49), the first terminal 422, and the biasing voltage source Vb1. The N-type transistor 462 may be, but not limited to, a MOSFET.

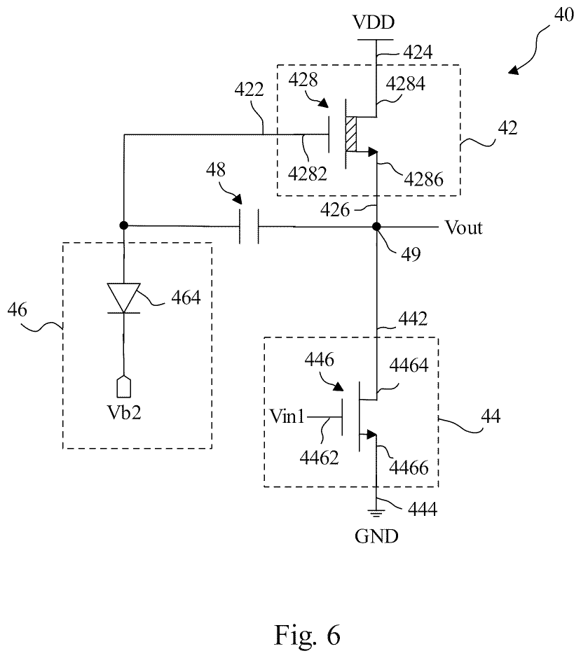

FIG. 6 shows a clamping circuit shown in FIG. 5 according to another embodiment of the present disclosure. In FIG. 6, the clamping circuit 46 includes a diode 464 and a biasing source Vb2. The diode 464 has an anode and a cathode coupled to the first terminal 422 and the biasing source Vb2 respectively.

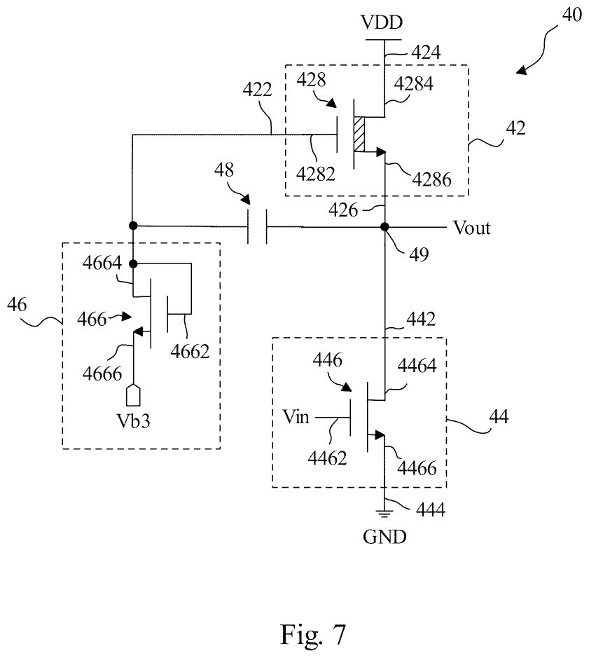

FIG. 7 shows a clamping circuit shown in FIG. 5 according to further embodiment of the present disclosure. In FIG. 6, the clamping circuit 46 includes an N-type transistor 466 and a biasing source Vb3. The N-type transistor 466 has a gate 4662, a drain 4664, and a source 4666. The gate 4662 is coupled to the drain 4664 so that the N-type transistor 466 forms a diode. The gate 4662 and the drain 4664, serving as the anode of the diode, are coupled to the first terminal 422. The source 4666, serving as the cathode of the diode, are coupled to the biasing source Vb3. The N-type transistor 466 may be, but not limited to, a MOSFET.

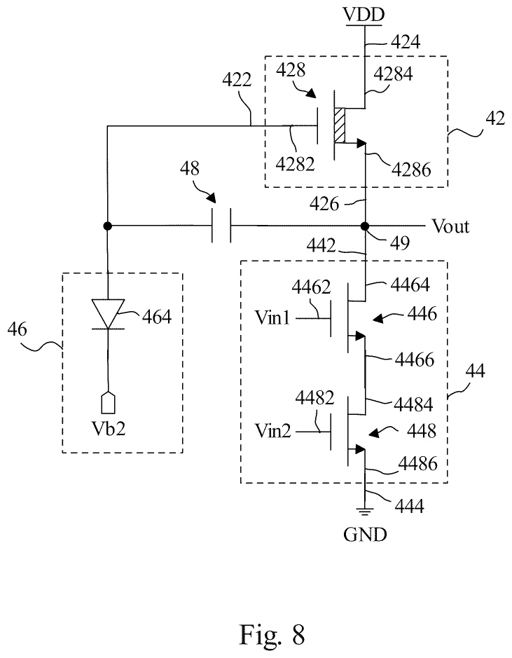

FIG. 8 shows a logic gate circuit shown in FIG. 4 implemented with a NAND gate according to an embodiment of the present disclosure. The logic gate circuit 40 of FIG. 8 is similar to that of FIG. 6. Their difference is that the N-type transistor circuit 44 of the logic gate circuit 40 of FIG. 8 includes not only the N-type enhancement-mode GaN transistor 446 but also an N-type enhancement-mode GaN transistor 448. In FIG. 8, the gate 4462, the drain 4464, and the source 4466 of the N-type enhancement-mode GaN transistor 446 are respectively coupled to the control signal Vin1, the fourth terminal 442, and the N-type enhancement-mode GaN transistor 448. The gate 4482, the drain 4484, and the source 4486 of the N-type enhancement-mode GaN transistor 448 are respectively coupled to a control signal Vin2, the source 4466, and the fifth terminal 444.

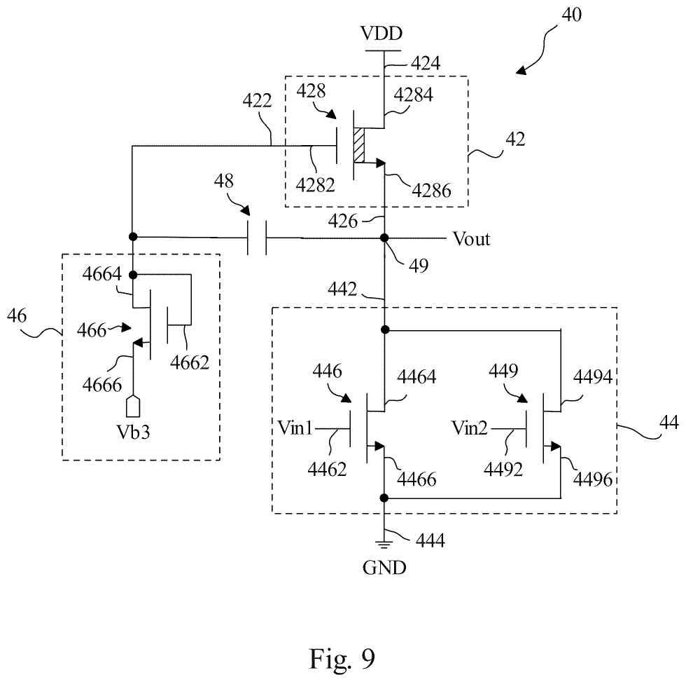

FIG. 9 shows a logic gate circuit shown in FIG. 4 implemented with a NOR gate according to an embodiment of the present disclosure. The logic gate circuit 40 of FIG. 9 is similar to that of FIG. 7. Their difference is that the N-type transistor circuit 44 of the logic gate circuit 40 of FIG. 9 includes not only the N-type enhancement-mode GaN transistor 446 but also an N-type enhancement-mode GaN transistor 449. In FIG. 9, the gate 4462, the drain 4464, and the source 4466 of the N-type enhancement-mode GaN transistor 446 are respectively coupled to the control signal Vin1, the fourth terminal 442, and the fifth terminal. The gate 4492, the drain 4494, and the source 4496 of the N-type enhancement-mode GaN transistor 449 are respectively coupled to the control signal Vin2, the fourth terminal 442, and the fifth terminal 444.

The foregoing embodiments only exemplify an inverter, a NAND gate, and a NOR gate, but the present disclosure is not limited thereto. The logic gate circuit 40 of the present disclosure can also be applied to other logic gates.

For the sake of explanation, the operating principle of the logic gate circuit of the present disclosure is explained follows based on the logic gate circuit 40 shown FIG. 5. When the control signal Vin is at a low level “0”, the N-type enhancement-mode GaN transistor 446 is turned off and the N-type depletion-mode GaN transistor 428 is turned on. Thus, the power supply voltage VDD charges the output 49 such that the voltage value of the output signal Vout rises to VDD. Namely, the output signal Vout transitions to a high level “1”. When the output signal Vout transitions to a high level “1”, the N-type transistor 462 is turned on and the N-type depletion-mode GaN transistor 428 is turned off. At this time, the voltage Vc across the capacitor 48 is equal to the turn-off voltage (or the threshold voltage) VTD of the N-type depletion-mode GaN transistor 428. The voltage value of the output signal Vout is equal to the voltage of the biasing voltage source Vb1 minus the voltage Vc across the capacitor 48. The biasing source Vb1 is set to VDD+VTD such that the voltage value of the output signal Vout is equal to VDD, thereby achieving rail-to-rail characteristics. When the control signal Vin is at a high level “1”, the N-type enhancement-mode GaN transistor 446 is turned on to couple the output 49 to the grounding terminal GND. Thus, the output signal Vout transitions to a low level “0” and the voltage value of the output signal Vout is 0 V. At this time, the N-type transistor 462 is turned off. Since the capacitor 48 stores the turn-off voltage VTD, the N-type depletion-mode GaN transistor 428 also remains in the off state and no leakage current is generated. In other embodiments, if the rail-to-rail characteristics are not considered, the voltage value of the biasing voltage source Vb1 may also be less than VDD+VTD.

Based on the foregoing operating principle of FIG. 5, it can be seen that the voltage value of the biasing voltage source Vb2 of FIG. 6 is less than or equal to VDD+VTD−VF and that the voltage value of the biasing voltage source Vb3 of FIG. 7 is less than or equal to VDD+VTD−VGS. VF is the forward biasing voltage of the diode 464. VGS is the voltage between the gate 4662 and the source 4666 of the N-type transistor 466.

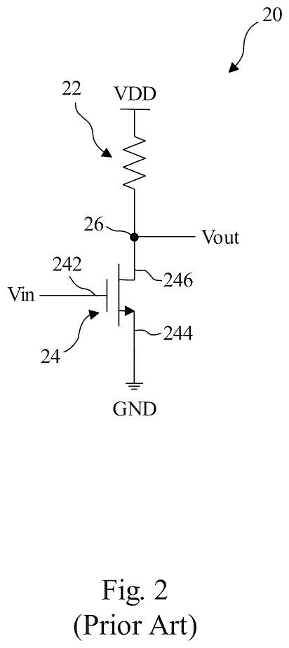

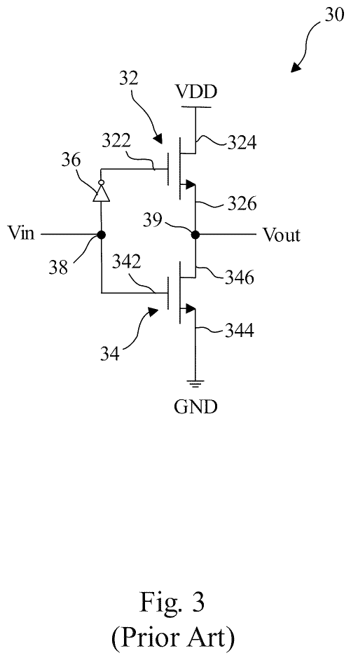

The transistors used in the logic gate circuit 40 of the present disclosure are all N-type transistors. Thus, they can be applied in processes where P-type transistors cannot be fabricated. Moreover, compared with the conventional logic gate circuit 20 in FIG. 2, the logic gate circuit 40 of the present disclosure has a good response speed without consuming additional power caused by leakage current. Compared with the conventional logic gate circuit 30 of FIG. 3, the logic gate circuit 40 of the present disclosure can achieve rail-to-rail characteristics.

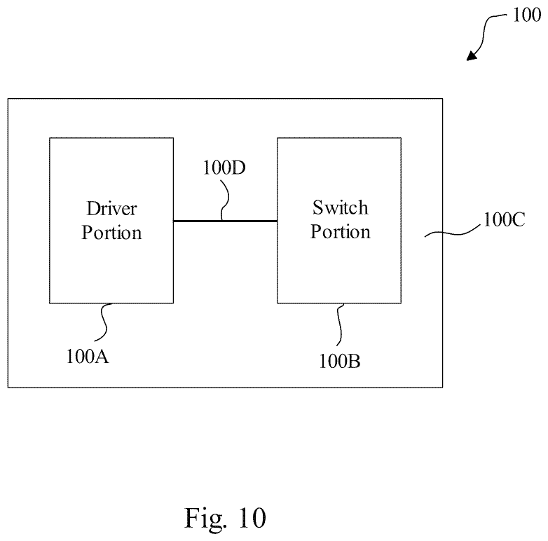

FIG. 10 shows a schematic diagram of a power chip 100 according to an embodiment. The power chip 100 includes a substrate 100C, a driver portion 100A on the substrate 100C, a switch portion 100B on the substrate 100C and an electric connection portion 100D which electrically connects the driver portion 100A and the switch portion 100B. The driver portion 100A is configured to receive a signal, such as PWM signal, for turning on or turning off the switch portion 100B through the electric connection portion 100D. In one embodiment, the substrate 100C comprises a growth substrate or a bonding substrate, wherein the substrate 100C comprises sapphire or silicon substrate. The driver portion 100A can be formed by a first semiconductor stack, wherein the first semiconductor stack comprises GaN series semiconductor material or Si. The switch portion 100B can be formed by a second semiconductor stack, wherein the second semiconductor stack comprises GaN series semiconductor material or Si. In one embodiment, the first semiconductor stack and the second semiconductor stack comprise the same material. In one embodiment, the driver portion 100A comprises the logic gate circuit 40 shown in FIG. 4 to FIG. 9, and the switch portion 100B comprises a depletion-mode GaN transistor, an enhancement-mode GaN transistor, or the combination thereof. In one embodiment, the power chip 100 can be applied for forming a Lift or an antihypertensive converter.

The embodiments described above are only to exemplify the present disclosure but not to limit the scope of the present disclosure. Therefore, any equivalent modification or variation according to the shapes, structures, features, or spirit disclosed by the present disclosure is to be also included within the scope of the present disclosure.

What is claimed is:

1. A logic gate circuit comprising:
a first N-type transistor circuit having a first terminal, a second terminal, and a third terminal, wherein the first N-type transistor circuit includes at least one N-type transistor;
a second N-type transistor circuit having a fourth terminal and a fifth terminal, wherein the fourth terminal is coupled to the third terminal and the second N-type transistor circuit includes at least one N-type transistor;
a capacitor coupled between the first terminal and the third terminal; and
a clamping circuit coupled to the first terminal and configured to clamp a voltage of the first terminal.

2. The logic gate circuit according to claim 1, wherein the first N-type transistor circuit comprises an N-type depletion-mode GaN transistor having a gate, a drain, and a source and the gate, the drain, and the source are respectively coupled to the first terminal, the second terminal, and the third terminal.

3. The logic gate circuit according to claim 1, wherein the second N-type transistor circuit comprises an N-type enhancement-mode GaN transistor having a gate, a drain, and a source and the gate, the drain, and the source are respectively coupled to a control signal, the fourth terminal, and the fifth terminal.

4. The logic gate circuit according to claim 1, wherein the second N-type transistor circuit comprises:
a first N-type enhancement-mode GaN transistor having a first gate, a first drain, and a first source, wherein the first gate and the first drain are respectively coupled to a first control signal and the fourth terminal; and
a second N-type enhancement-mode GaN transistor having a second gate, a second drain, and a second source, wherein the second gate, the second drain, and the second source are respectively coupled to a second control signal, the first source, and the fifth terminal.

5. The logic gate circuit according to claim 1, wherein the second N-type transistor circuit comprises:
a first N-type enhancement-mode GaN transistor having a first gate, a first drain, and a first source, wherein the first gate, the first drain, and the first source are respectively coupled to a first control signal, the fourth terminal, and the fifth terminal; and
a second N-type enhancement-mode GaN transistor having a second gate, a second drain, and a second source, wherein the second gate, the second drain, and the second source are respectively coupled to a second control signal, the fourth terminal, and the fifth terminal.

6. The logic gate circuit according to claim 1, wherein the clamping circuit comprises:
an N-type transistor having a drain, a source, and a gate, wherein the drain is coupled to the first terminal and the gate is coupled to the third terminal; and
a biasing voltage source coupled to the source and configured to provide a biasing voltage for the source.

7. The logic gate circuit according to claim 1, wherein the clamping circuit comprises:
a diode having an anode and a cathode, wherein the anode is coupled to the first terminal; and
a biasing voltage source coupled to the cathode and configured to provide a biasing voltage for the cathode.

8. The logic gate circuit according to claim 7, wherein the diode is composed of an N-type transistor.

9. A power chip, comprising:
a driver portion;
a switch portion; and
an electric connection portion electrically connecting the driver portion and the switch portion,
wherein the driver portion comprises:
a first N-type transistor circuit having a first terminal, a second terminal, and a third terminal, wherein the first N-type transistor circuit includes at least one N-type transistor;
a second N-type transistor circuit having a fourth terminal and a fifth terminal, wherein the fourth terminal is coupled to the third terminal and the second N-type transistor circuit includes at least one N-type transistor;
a capacitor coupled between the first terminal and the third terminal; and
a clamping circuit coupled to the first terminal and configured to clamp a voltage of the first terminal.

10. The power chip according to claim 9, further comprising a substrate for carrying the driver portion and the switch portion.

11. The power chip according to claim 9, wherein the driver portion comprises a first semiconductor material and the switch portion comprises a second semiconductor material, and the first semiconductor material and the second semiconductor material are the same.

12. The power chip according to claim 11, wherein the first semiconductor material comprises GaN series semiconductor.

13. The power chip according to claim 9, wherein the first N-type transistor circuit comprises an N-type depletion-mode GaN transistor having a gate, a drain, and a source and the gate, the drain, and the source are respectively coupled to the first terminal, the second terminal, and the third terminal.

14. The power chip according to claim 9, wherein the second N-type transistor circuit comprises an N-type enhancement-mode GaN transistor having a gate, a drain, and a source and the gate, the drain, and the source are respectively coupled to a control signal, the fourth terminal, and the fifth terminal.

15. The power chip according to claim 9, wherein the second N-type transistor circuit comprises:
a first N-type enhancement-mode GaN transistor having a first gate, a first drain, and a first source, wherein the first gate and the first drain are respectively coupled to a first control signal and the fourth terminal; and
a second N-type enhancement-mode GaN transistor having a second gate, a second drain, and a second source, wherein the second gate, the second drain, and the second source are respectively coupled to a second control signal, the first source, and the fifth terminal.

16. The power chip according to claim 9, wherein the second N-type transistor circuit comprises:
a first N-type enhancement-mode GaN transistor having a first gate, a first drain, and a first source, wherein the first gate, the first drain, and the first source are respectively coupled to a first control signal, the fourth terminal, and the fifth terminal; and
a second N-type enhancement-mode GaN transistor having a second gate, a second drain, and a second source, wherein the second gate, the second drain, and the second source are respectively coupled to a second control signal, the fourth terminal, and the fifth terminal.

17. The power chip according to claim 9, wherein the clamping circuit comprises:
an N-type transistor having a drain, a source, and a gate, wherein the drain is coupled to the first terminal and the gate is coupled to the third terminal; and
a biasing voltage source coupled to the source and configured to provide a biasing voltage for the source.

18. The power chip according to claim 9, wherein the clamping circuit comprises:
a diode having an anode and a cathode, wherein the anode is coupled to the first terminal; and
a biasing voltage source coupled to the cathode and configured to provide a biasing voltage for the cathode.

19. The power chip according to claim 18, wherein the diode is composed of an N-type transistor.

20. The power chip according to claim 10, wherein the substrate comprises a growth substrate or a bonding substrate.
